(19) United States
(12) Patent Application Publication
(10) Pub. No.: US 2026/0043851 A1
(43) Pub. Date: Feb. 12, 2026

(54) MOTOR MONITORING DEVICE

(71) Applicant: FANUC CORPORATION, Yamanashi (JP)

(72) Inventors: Kenji SHIMIZU, Yamanashi (JP); Makoto HAGA, Yamanashi (JP)

(73) Assignee: FANUC CORPORATION, Yamanashi (JP)

(21) Appl. No.: 19/100,354

(22) PCT Filed: Oct. 5, 2022
(86) PCT No.: PCT/JP2022/037311

§ 371 Date: Jan. 31, 2025

(51) Int. Cl. G01R 31/34

(52) U.S. Cl. CPC G01R 31/343

(57) ABSTRACT

A motor monitoring device according to one aspect of the present disclosure comprises: a rotational speed acquisition unit that acquires the rotational speed of one or more motors driven by a plurality of alternatively used windings; an output value acquisition unit that acquires the output value of the motor(s); a winding identification unit that identifies the winding in use; a load characteristic acquisition unit that acquires load characteristic information about the winding identified by the winding identification unit for the motor(s); and a graph display unit that plots a marker indicating a combination of the rotational speed and the output value in a graph area of which one axis is the rotational speed and the other axis is the output value. The graph display unit includes: a graph area setting unit that, with regard to expected combinations of the rotational speed and the output value, divides the graph area into a plurality of load zones with different load levels on the basis of a plurality of the load characteristic information, and displays the plurality of load zones in an identifiable manner; and a plotting unit that plots the marker in the graph area.

### TECHNICAL FIELD

The present invention relates to a motor monitoring device.

### BACKGROUND ART

A motor such as a spindle motor of a machine tool, where the load can vary greatly, for example, can experience overheating due to heat buildup in a situation in which the motor is kept in a high-load state. For such a motor, various time ratings can be set that allow the motor to operate without experiencing overheating under specified conditions. Examples of time ratings include those provided by JIS-C4034-1, such as continuous rating, which allows the motor to operate continuously, short time rating, which allows the motor to operate for a specified period of time (load time) from room temperature, and intermittent duty rating, which allows the motor to operate for a specified period of time within a predetermined cycle time (load time ratio).

For example, it is envisioned that the actual operating state of a motor in a machine tool is tracked, and a setting value such as for the motor speed is adjusted to reduce the margin against overheating, enabling more efficient machining. As a device that makes it possible to track the current operating state of a motor, a known load meter plots the current values of the rotation number and the power output of the motor on a graph that shows lines indicating the various ratings mentioned above, with one axis representing the rotation number and the other axis representing the power output (see, for example, Patent Document 1).

### CITATION LIST

### Patent Document

Patent Document 1: Japanese Unexamined Patent Application, Publication No. H10-90011

### DISCLOSURE OF THE INVENTION

### Problems to be Solved by the Invention

A known device configuration includes a plurality of motors that are selectively used to drive a single shaft. Another known device configuration includes a plurality of winding paths that are selectively used to drive a single motor. It is desirable to accurately track the state of a motor of interest in such device configurations.

### Means for Solving the Problems

A motor monitoring device according to an embodiment of the present disclosure includes: a rotation number acquisition unit configured to acquire a rotation number of at least one motor that is driven by one winding of a plurality of windings which is used selectively; an output value acquisition unit configured to acquire a output value of the at least one motor; a winding identification unit configured to identify the one winding being used; a load characteristic acquisition unit configured to acquire load characteristic information of the one winding identified by the winding identification unit for the at least one motor; and a graph display unit configured to plot a marker indicating a combination of the rotation number and the output value in a graph area with one axis representing the rotation number and another axis representing the output value, wherein the graph display unit has a graph area setting unit configured to divide, based on the load characteristic information, the graph area into a plurality of load zones with different load levels for expected combinations of the rotation number and the output value, and display the plurality of load zones in a distinguishable manner, and a plotting unit configured to plot the marker in the graph area.

### Effects of the Invention

According to the present disclosure, it is possible to easily track the state of the motor.

### BRIEF DESCRIPTION OF THE DRAWINGS

FIG. 1 is a block diagram illustrating a configuration of a machine tool including a motor monitoring device according to a first embodiment of the present disclosure; and

FIG. 2 is a diagram showing an example of a screen displayed in the motor monitoring device shown in FIG. 1.

### PREFERRED MODE FOR CARRYING OUT THE INVENTION

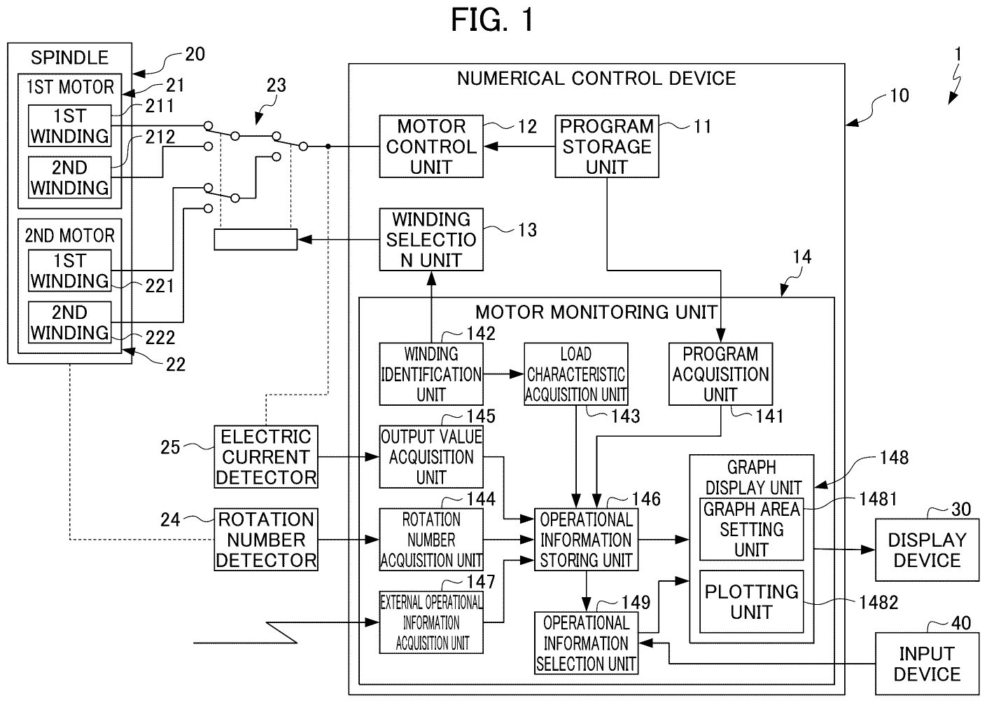

The following describes an embodiment of the present disclosure with reference to the drawings. FIG. 1 is a block diagram illustrating a configuration of a machine tool 1 including a motor monitoring device according to a first embodiment of the present disclosure.

The machine tool 1 includes a numerical control device 10, which is an embodiment of the motor monitoring device according to the present invention, a spindle 20 that is controlled by the numerical control device 10, a display device 30 that displays screens in accordance with directions by the numerical control device 10, and an input device 40 that is used by a user for input to the numerical control device 10.

The numerical control device 10 can be implemented through one or more computer devices that have memory, a processor (CPU), an input/output interface, and the like, and execute an appropriate control program. The constituent elements of the numerical control device 10 described below are distinguishable based on different functions of the numerical control device 10 (operations of the processor), and do not have to be clearly distinguishable in terms of physical configuration and program configuration.

The spindle 20 is driven by one of a plurality of motors (a first motor 21 and a second motor 22) that is used selectively. The first motor 21 has a plurality of windings (a first winding 211 and a second winding 212) one of which is used selectively. Likewise, the second motor 22 has a plurality of windings (a first winding 221 and a second winding 222) one of which is used selectively. In other words, the spindle 20 is driven by one of the four windings 211, 212, 221, and 222, which is used selectively. The spindle 20 is typically a drive shaft that rotates and drives a cutting tool or a workpiece, and the load thereon can vary independently of the rotation number thereof, depending on machining conditions.

The machine tool 1 further includes a switching unit 23 for selecting one of the windings 211, 212, 221, and 222, a rotation number detector 24 that detects the rotation number of the spindle 20, and an electric current detector 25 that detects the electric current supplied to the winding 211, 212, 221, or 222 driving the spindle 20. The switching unit 23 may be composed of a plurality of relays that are controlled by the numerical control device 10. The rotation number detector 24 and the electric current detector 25 may be respectively composed of known sensors. The electric current detector 25 may be disposed so as to detect the electric current in an electrical circuit located upstream of the switching unit 23.

The display device 30 is a known display that performs display in accordance with signals inputted from the numerical control device 10. The display device 30 may be integrated with the numerical control device 10. The input device 40 is provided for the user to input information to the numerical control device 10. The input device 40 may have a known configuration, and examples thereof include a keyboard and a mouse. The input device 40 may be also integrated with the numerical control device 10. Alternatively, the input device 40 may be integrated with the display device 30. Specifically, the display device 30 and the input device 40 may be provided as a single input/output device such as a touch panel.

The numerical control device 10 in the present embodiment includes a program storage unit 11, a motor control unit 12 that controls operation of motors for driving drive shafts of the machine tool 1 including the spindle 20, a winding selection unit 13 that selects one of the windings 211, 212, 221, and 222 by controlling the switching unit 23, and a motor monitoring unit 14 that executes functions of the motor monitoring device according to the present disclosure.

The program storage unit 11 stores therein a machining program to be executed in the machine tool 1. The machining program contains a plurality of blocks that each specify a unit operation of the machine tool 1. Each of the blocks contains one or more words, each of which is a combination of a plurality of characters (letters). In general, each block is assigned a sequence number for identifying the block at the beginning.

The motor control unit 12 executes a machining procedure described in the machining program by controlling the spindle 20 and other drive shafts of the machine tool 1, specifically by controlling the winding electric current of each motor, in accordance with the machining program. The configuration of the motor control unit 12 is the same as that in a known numerical control device, and thus detailed description thereof is omitted.

The winding selection unit 13 controls the switching unit 23 to connect only one of the windings 211, 212, 221, and 222 of the spindle 20 to the motor control unit 12.

The motor monitoring unit 14 includes a program acquisition unit 141, a winding identification unit 142, a load characteristic acquisition unit 143, a rotation number acquisition unit 144, an output value acquisition unit 145, an operational information storing unit 146, an external operational information acquisition unit 147, a graph display unit 148, and an operational information selection unit 149.

The program acquisition unit 141 acquires, from the program storage unit 11, a machining program that specifies the operation of the motor 21 or 22 of the spindle 20 to be monitored.

The winding identification unit 142 acquires, from the winding selection unit 13, information identifying the selected winding 211, 212, 221, or 222.

The load characteristic acquisition unit 143 acquires load characteristic information indicating load characteristics of the selected winding 211, 212, 221, or 222 identified by the winding identification unit 142. Preferably, the load characteristic information includes a plurality of time ratings. The load characteristic acquisition unit 143 may acquire the load characteristic information from an internal storage device of the motor monitoring unit 14 or from an external source such as a server.

The rotation number acquisition unit 144 acquires, from the rotation number detector 24, the rotation number of the selected motor 21 or 22, that is, the rotation number of the spindle 20. The rotation number acquisition unit 144 may acquire information from the motor control unit 12 and the winding selection unit 13, and calculate the rotation number of the spindle 20 from the thus acquired information.

The output value acquisition unit 145 acquires, for example, output values such as an electric current value, a power value, and a torque value of the spindle 20. The output value acquisition unit 145 of the present embodiment is contemplated to acquire the electric current value of the spindle 20 from the electric current detector 25, and use the power value and the torque value calculated from the electric current value as the output values. However, the output value acquisition unit 145 may be configured to take a detected value such as the electric current value as the output value. The output value acquisition unit 145 may acquire output values or values necessary to calculate the output values from the motor control unit 12. The output value acquisition unit 145 may acquire one kind of output value or three or more kinds of output values.

The operational information storing unit 146 stores the winding 211, 212, 221, or 222 identified by the winding identification unit 142 and the load characteristic information acquired by the load characteristic acquisition unit, and the rotation number acquired by the rotation number acquisition unit 144, the output value(s) acquired by the output value acquisition unit 145, and the information identifying the corresponding block of the machining program acquired by the program acquisition unit 141, such as a sequence number, a line number, or the like, in association with each other. In other words, the operational information storing unit 146 stores a number assigned to the winding 211, 212, 221, or 222, and the rotation and the output value of the spindle in such a manner that the block of the machining program executed when these values were obtained is identifiable. The operational information that is stored by the operational information storing unit 146 may further include, for example, information indicating the state of the spindle 20, in particular the state of the winding 211, 212, 221, or 222, such as the temperature of the winding 211, 212, 221, or 222.

Typically, the rotation number and the output value are acquired in short cycles, and thus a plurality of combinations of the rotation number and the output value may be acquired with respect to a single block. However, the operational information storing unit 146 may store one set of data per block so that the sequence number is a unique key that does not duplicate across a plurality of sets of data. In this case, the rotation number and the output value to be stored corresponding to each block are each a representative value thereof. Preferably, in order to ensure safety, values that each indicate the highest load (maximum values in the case of the rotation number and the electric current value) among the values of the rotation number and the output values corresponding to each block are used as the representative values for the block.

The external operational information acquisition unit 147 acquires operational information acquired in another motor monitoring device (numerical control device) from the other motor monitoring device, a management computer that manages a plurality of motor monitoring devices, an external database, or the like. That is, the external operational information acquisition unit 147 is a constituent element for sharing operational information among a plurality of motor monitoring devices.

The graph display unit 148 displays, on a screen displayed on the display device 30, a graph plotting a marker indicating a combination of the rotation number and the output value in a graph area with one axis representing the rotation number and the other axis representing the output value. The graph display unit 148 may display a graph showing a single output value, or may display graphs respectively showing a plurality of output values in an arrangement.

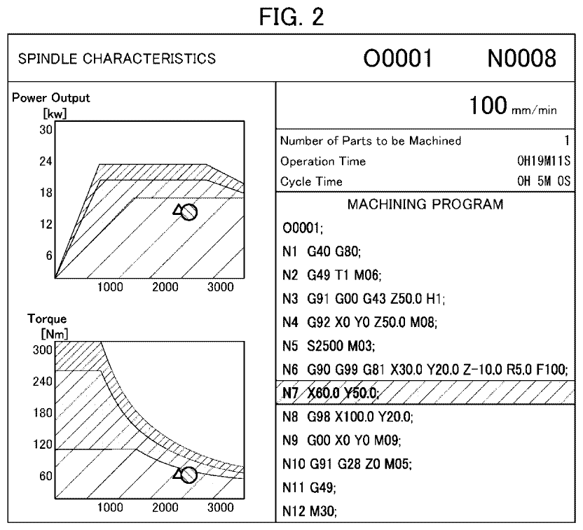

In order to enable the user to easily understand the relationship between the machining program, and the rotation number and the output value, preferably, the graph display unit 148 displays the graph along with a corresponding portion of the program, as in an example shown in FIG. 2.

The graph display unit 148 has a graph area setting unit 1481 that divides the graph area into a plurality of load zones and displays the plurality of load zones in a distinguishable manner, and a plotting unit 1482 that plots a marker indicating a combination of the actual rotation number and the actual output value in the graph area.

The graph area setting unit 1481 divides, based on the load characteristic information pertaining to the selected winding 211, 212, 221, or 222, the graph area into a plurality of load zones with different load levels for expected combinations of the rotation number and the output value. Typically, the graph area setting unit 1481 may be configured to divide the graph area into three or more load zones based on boundaries corresponding to different time ratings. The load zones in the graph area are varied based on the winding 211, 212, 221, or 222 that is used. This configuration enables the user to easily understand the load state (risk level or safety level) of the spindle 20.

Preferably, the graph area setting unit 1481 displays the plurality of load zones in a distinguishable manner using different colors or patterns, which enable the user to easily know which load zone the combination of the rotation number and the output value belongs to. The use of different colors or patterns, such as blue, yellow, and red, that enable the user to intuitively know how high the load level of a load zone of interest is makes it easier to know the risk level of the operating state of the spindle 20.

The operating state of the spindle 20 can be maintained without limitation in terms of the load thereon as long as the combination of the rotation number and the output value of the spindle 20 is within the zone corresponding to the continuous rating. For this reason, the upper limit of the load zone with the lowest load level is preferably a curve representing the continuous rating.

The graph area setting unit 1481 preferably uses a line connecting each maximum value among values at the same rotation number of a plurality of time ratings (for example, a short time rating and an intermittent duty rating with different load time ratios) as a boundary of one of the plurality of load zones, preferably as the lower limit of the load zone with the highest load level. The combination of the rotation number and the output value being plotted in a zone beyond this boundary means a risky output state that can cause immediate malfunction. This also means that, as long as the combination is within this boundary, short-time operation is unlikely to cause any issues.

The graph area setting unit 1481 may be configured to allow selection of at least one of the boundaries of the plurality of load zones in accordance with the user's input. Specifically, the graph area setting unit 1481 may be configured to allow selection of a boundary of a load zone from among a continuous rating, the maximum values of a plurality of time ratings, and a plurality of short time ratings with different load times and a plurality of intermittent duty ratings with different load time ratios such as described above. This configuration makes it possible to set load zones that are deemed appropriate in consideration of the details of the machining to be performed by the machine tool 1, so that the user can know the risk level or the safety level of the spindle 20 more adequately.

The plotting unit 1482 plots the combination of the rotation number and the output value of the winding 211, 212, 221, or 222 being used for the spindle 20. The plotting unit 1482 may plot, for example, the combination of the rotation number and the output value while indicating the magnitude of a state value representing the state of the spindle 20, such as the winding temperature, by varying, for example, the shape, size, color, or pattern of the marker. This configuration enables the user to simultaneously know the state value that may be affected by the previous operating state of the spindle 20 as well as the current operating state of the spindle 20 indicated by the rotation number and the output value. In some cases, for example, even if the state value indicates that the temperature of the spindle 20 is high, the user can determine that there is no possibility of the temperature of the spindle 20 rising further as long as the current load level is low. In other cases, even if the current load level is not so high, the user can determine that maintaining the current operating state is likely to cause overheating shortly. The marker may be in the form having an outer edge that facilitates distinction from the color or the pattern of the graph area and an inner filled region that indicates the state value. As described above, as a result of the plotting unit 1482 indicating the state value using the form of the marker, the user can understand the operating state of the spindle 20 from multiple perspectives.

In addition to the marker indicating the current combination of the rotation number and the output value, the plotting unit 1482 may plot another marker indicating a combination of the rotation number and the output value obtained in a case where the same block of the same program as the currently executed block was executed in the past. Preferably, the marker indicating the current state and the marker indicating the past performance are displayed in a distinguishable manner. In FIG. 2, a round marker is plotted to indicate the current state, and a triangular marker is plotted to indicate the past performance. This configuration enables the user to easily check whether or not there is an abnormal load increase, in addition to the margin between the operating state of the spindle 20 and the specifications of the spindle 20.

The marker indicating the past performance to be plotted in the graph area may be, for example, in the form of cross-shaped auxiliary lines extending in longitudinal and lateral directions in the graph area, in order to facilitate distinction from the marker indicating the current state. The past performance to be plotted may be an average value of all relevant sets of operational information, or may be a value or a range calculated from one or more sets of operational information selected by the operational information selection unit 149.

The operational information selection unit 149 selects a set of operational information to be plotted by the plotting unit 1482 from among a plurality of sets of operational information obtained in a case where the same operation program as the currently executed operation program was executed. The operational information selection unit 149 may be configured to specify one or more sets of operational information on the spindle 20 that is considered normal, in accordance with a predetermined algorithm. As a specific example, the operational information selection unit 149 may be configured to select one or more sets of operational information to be plotted by the plotting unit 1482 by a statistical method using the mean, standard deviation, or the like. The operational information selection unit 149 may be also configured to provide an interface for requesting the user to select a plurality of sets of operational information.

The numerical control device 10 according to the present embodiment acquires the load characteristic information of the winding being used, divides the graph area into load zones based on the load characteristic information, and plots the combination of the rotation number and the output value. Thus, the user can easily know the safety level of the operating state of the motor based on the load zone where the combination of the rotation number and the output value is plotted.

The following further discloses additional remarks regarding the foregoing embodiment and modification examples thereof.

### Additional Remark 1

A motor monitoring device (10) includes: a rotation number acquisition unit (144) configured to acquire a rotation number of at least one motor (21, 22) that is driven by one winding of a plurality of windings (211, 212, 221, and 222) which is used selectively; an output value acquisition unit (145) configured to acquire a output value of the at least one motor (21, 22); a winding identification unit (142) configured to identify the one winding (211, 212, 221, or 222) being used; a load characteristic acquisition unit (143) configured to acquire load characteristic information of the one winding (211, 212, 221, or 222) identified by the winding identification unit (142) for the at least one motor (21, 22); and a graph display unit (148) configured to plot a marker indicating a combination of the rotation number and the output value in a graph area with one axis representing the rotation number and another axis representing the output value, wherein the graph display unit (148) has a graph area setting unit (1481) configured to divide, based on the load characteristic information, the graph area into a plurality of load zones with different load levels for expected combinations of the rotation number and the output value, and display the plurality of load zones in a distinguishable manner, and a plotting unit (1482) configured to plot the marker in the graph area.

### Additional Remark 2

The motor monitoring device (10) according to the additional remarks 1 may further include: a program acquisition unit (141) configured to acquire an operation program containing a plurality of blocks that specify operations of the at least one motor (21, 22); and an operational information storing unit (146) configured to store operational information containing the load characteristic information, the rotation number, and the output value associated with the blocks, wherein the plotting unit (1482) may plot the marker indicating a current combination of the rotation number and the output value, and the marker indicating a combination of the rotation number and the output value obtained in a case where the same block as the currently executed block was executed in the past.

### Additional Remark 3

The motor monitoring device (10) according to the additional remarks 2 may further include an operational information selection unit (149) configured to select a set of operational information to be plotted by the plotting unit (1482) from among a plurality of sets of operational information obtained in a case where the same operation program as the currently executed operation program was executed.

### Additional Remark 4

The motor monitoring device (10) according to the additional remarks 2 or 3 may further include an external operational information acquisition unit (147) configured to acquire the operational information from an external source.

Although the present disclosure has been described in detail above, the present disclosure is not limited to the foregoing individual embodiments. Various changes, such as additions, substitutions, alterations, and partial omissions, may be made to the foregoing embodiments to the extent that such changes do not depart from the gist of the present disclosure, or to the extent that such changes do not depart from the gist of the present disclosure that is derived from the appended claims or the equivalents thereof.

The motor monitoring device according to the present disclosure may be independent of a numerical control device for controlling a machine tool, and may be configured to enable a user to check the state of a motor other than a spindle motor of a machine tool or a motor other than those provided in a machine tool. For example, the motor monitoring device according to the present disclosure may be a device obtained by adding the functions of the motor monitoring unit of the embodiment described above to a management computer for managing one or more numerical control devices.

In the motor monitoring device according to the present disclosure, the information storing unit, the program acquisition unit, the operational information storing unit, the external operational information acquisition unit, and the operational information selection unit may be omitted. In other words, the motor monitoring device according to the present disclosure may only have the function of displaying the current load state of a motor in real time.

### EXPLANATION OF REFERENCE NUMERALS

1: Machine tool
10: Numerical control device (motor monitoring device)
11: Program storage unit
12: Motor control unit
13: Winding selection unit
14: Motor monitoring unit
141: Program acquisition unit
142: Winding identification unit
143: Load characteristic acquisition unit
144: Rotation number acquisition unit
145: Output value acquisition unit
146: Operational information storing unit
147: External operational information acquisition unit
148: Graph display unit
1481: Graph area setting unit
1482: Plotting unit
149: Operational information selection unit
20: Spindle
21, 22: Motor
211, 212, 221, 222: Winding
23: Switching unit
24: Rotation number detector
25: Electric current detector
30: Display device
40: Input device

1. A motor monitoring device comprising:
a rotation number acquisition unit configured to acquire a rotation number of at least one motor that is driven by one winding of a plurality of windings which is used selectively;
an output value acquisition unit configured to acquire a output value of the at least one motor;
a winding identification unit configured to identify the one winding being used;
a load characteristic acquisition unit configured to acquire load characteristic information of the one winding identified by the winding identification unit for the at least one motor; and
a graph display unit configured to plot a marker indicating a combination of the rotation number and the output value in a graph area with one axis representing the rotation number and another axis representing the output value, wherein
the graph display unit has
a graph area setting unit configured to divide, based on the load characteristic information, the graph area into a plurality of load zones with different load levels for expected combinations of the rotation number and the output value, and display the plurality of load zones in a distinguishable manner, and
a plotting unit configured to plot the marker in the graph area.

2. The motor monitoring device according to claim 1, further comprising:
a program acquisition unit configured to acquire an operation program containing a plurality of blocks that specify operations of the at least one motor; and
an operational information storing unit configured to store operational information containing the load characteristic information, the rotation number, and the output value associated with the blocks, wherein
the plotting unit plots the marker indicating a current combination of the rotation number and the output value, and the marker indicating a combination of the rotation number and the output value obtained in a case where a same block as a currently executed block was executed in the past.

3. The motor monitoring device according to claim 2, further comprising an operational information selection unit configured to select a set of operational information to be plotted by the plotting unit from among a plurality of sets of operational information obtained in a case where a same operation program as a currently executed operation program was executed.

4. The motor monitoring device according to claim 2, further comprising an external operational information acquisition unit configured to acquire the operational information from an external source.
